(19) United States
(12) Patent Application Publication
(10) Pub. No.: US 2010/0108133 A1
(43) Pub. Date: May 6, 2010

(54) Thin Film Semiconductor Photovoltaic Device

(76) Inventors: Venkata Adiseshaiah Bhagavatula, Big Flats, NY (US); Glenn Eric Kohnke, Corning, NY (US)

Correspondence Address: CORNING INCORPORATED, SP-TI-3-1, CORNING, NY, 14831, US

(21) Appl. No.: 12/263,583

(22) Filed: Nov. 3, 2008

(51) Int. Cl. H01L 31/00

(52) U.S. Cl. 136/256

(57) ABSTRACT

A substantially transparent substrate having first and second major surfaces and a plurality of side surfaces; a thin-film semiconductor layer coupled to the first major surface of the substrate and including first and second major surfaces and at least one photo-sensitive p-n junction therein; and a light directing feature operable to cause incident light to propagate through the substrate and into the semiconductor layer in a waveguide mode such that the light reflects a plurality of times between the first and second major surfaces of the semiconductor layer and impinges upon the p-n junction a plurality of times

### BACKGROUND

The present invention relates to methods and apparatus for providing a photovoltaic device, such as a device in which a thin film, semiconductor photo-sensitive layer is coupled to a transparent substrate.

Photovoltaic solar cells are attractive mechanisms for generating electrical energy as they do not produce greenhouse gasses as a byproduct. There are two basic configurations for conventional thin-film photovoltaic solar-cell technology: the superstrate configuration and the substrate configuration. In the superstrate configuration, incident light passes through a transparent material that supports an active semiconductor material disposed thereon. In the substrate configuration, light is incident on the active semiconductor material and then reaches the substrate. FIG. 1 illustrates a conventional superstrate photovoltaic device 10, which includes a substrate 12 on which a semiconductor material 14 is disposed. The semiconductor material (which may be crystalline silicon) includes a p-n junction 16, which has the characteristic of creating unbound charges (electrons and holes) and generating a voltage V across a pair of conductors when light passes through the junction. In this configuration, the substrate is transparent and permits the light to pass to the semiconductor material 14.

The primary issues with conventional solar cell approaches are cost, efficiency, and form factor associated with fabrication of the solar cell. Various single crystal or thin film processes have been developed in an attempt to address these issues. Single crystal solar cells can have high efficiency, but the process is quite expensive. In such cases, especially with expensive III-V solar cells and multi-junction solar cells, solar concentrators are employed. Thin film semiconductor fabrication techniques can be less expensive, but the energy conversion efficiency is normally quite low. As the semiconductor layers are made thin (in order to reduce cost), i.e., less than about 1 um for silicon, the absorption of infrared energy by the cell becomes very low and the efficiency falls quite dramatically.

Referring again to FIG. 1, in some prior art configurations, a light scattering layer (e.g., formed from a roughened transparent conductive oxide) may be disposed between the substrate 12 and the semiconductor 14. Another discontinuity (such as a metallization layer) may be disposed on the opposing surface of the semiconductor material 14. The scattering layer and metallization layer may cause some of the light to become trapped within the semiconductor material 14 because the light would tend to bounce off of the respective layers at respective distributions of angles (light scattering and trapping). While this approach improves solar energy conversion at the p-n junction 16, complete light trapping is not possible due to scattering light out of the structure.

In silicon-based solar cells, which include amorphous, micro- or nano-crystalline, polycrystalline and/or crystalline materials, layer thicknesses are typically less than 5 um and light trapping is critical. For amorphous and microcrystalline silicon solar cells, transparent conductive oxide (TCO) layers are typically used due to the poor conductivity of the doped layers. In the superstrate geometry, the TCO layers are textured (as discussed above) to create a light scattering interface between the TCO and the silicon semiconductor layer. There is a trade-off between the light scattering performance of the surface textures and the electrical transport characteristics of the silicon in the case of microcrystalline silicon. This impacts the light trapping performance of single-junction microcrystalline cells and amorphous/microcrystalline (micromorph) tandem junction cells. The same limitations apply to the substrate geometry. In the case of polycrystalline or crystalline thin film Si solar cells, scattering layers are also employed. Polycrystalline cells may have scattering introduced at the substrate/Si interface in the superstrate geometry while crystalline Si solar cells typically have a planar substrate/Si interface. Again, textured silicon is used at the back reflector to provide scattering. In the substrate configuration, polycrystalline and crystalline silicon solar cells employ scattering at the air/silicon interface and/or the silicon/substrate interface. To eliminate process steps and improve performance, there is a need to provide light trapping without the use of textured surfaces.

For the above reasons, the cost of solar energy is about 2-3 times more expensive than conventional grid power. In some solar energy sectors, such as roof top applications in homes, apartment complexes, industrial parks or applications where grid power is not easily available, low weight and form factor may be a significant advantage. Accordingly, there is a need in the art for a new approach to providing photovoltaic solar cells, which enjoy characteristics of low cost, high efficiency, low weight and low form factor.

### SUMMARY

In accordance with one or more embodiments, a photovoltaic device includes: a substantially transparent substrate having first and second major surfaces and a plurality of side surfaces; a thin-film semiconductor layer coupled to the first major surface of the substrate and including first and second major surfaces and at least one photo-sensitive p-n junction therein; and a light directing feature operable to cause incident light to propagate through the substrate and into the semiconductor layer in a waveguide mode such that the light reflects a plurality of times between the first and second major surfaces thereof and impinges upon the p-n junction a plurality of times.

The thickness of the semiconductor layer may be less than about 2 um, such as about 1-2 um. The substantially transparent substrate may be formed from at least one of glass, glass ceramic, and polymer.

Other aspects, features, advantages, etc. will become apparent to one skilled in the art when the description of the invention herein is taken in conjunction with the accompanying drawings.

### BRIEF DESCRIPTION OF THE DRAWINGS

For the purposes of illustrating the various aspects of the invention, there are shown in the drawings forms that are presently preferred, it being understood, however, that the invention is not limited to the precise arrangements and instrumentalities shown.

FIG. 1 is a side view of a photovoltaic device in accordance with the prior art;

FIG. 2 is a perspective view of a photovoltaic device in accordance with one or more aspects of the present invention;

FIG. 3 is a side view of a photovoltaic device in accordance with one or more further aspects of the present invention;

FIG. 4 is a side view of a further photovoltaic device in accordance with one or more further aspects of the present invention;

FIG. 5 is a side view of a further photovoltaic device in accordance with one or more further aspects of the present invention;

FIG. 6 is a side view of a further photovoltaic device in accordance with one or more further aspects of the present invention;

FIG. 7 is a side view of a further photovoltaic device in accordance with one or more further aspects of the present invention;

FIG. 8 is a side view of a further photovoltaic device in accordance with one or more further aspects of the present invention;

FIG. 9 is a side view of a further photovoltaic device in accordance with one or more further aspects of the present invention;

FIG. 10 is a side view of a further photovoltaic device in accordance with one or more further aspects of the present invention;

FIG. 11A is a side view of a further photovoltaic device in accordance with one or more further aspects of the present invention;

FIG. 11B is a side view of an alternative light directing element for use with the photovoltaic device of FIG. 11A; and

FIG. 12A, 12B are graphs illustrating simulation results of certain parameters of merit associated with a basic operational concept of the photovoltaic devices of the present invention.

### DETAILED DESCRIPTION

With reference to the drawings, wherein like numerals indicate like elements, there is shown in FIG. 2 a perspective view of a photovoltaic device 100 in accordance with one or more embodiments of the present invention. The photovoltaic device 100 includes a substantially transparent substrate 102 having first and second major surfaces 108, 110 and a plurality of side surfaces, generally forming a right parallelepiped. A semiconductor layer 104 is coupled to the first major surface 108 of the substrate 102 and includes at least one photo-sensitive p-n junction 106.

The structure 100 is considered herein to exhibit composite waveguide characteristics because, as will be discussed in detail below, light propagates within the structure in a waveguide mode. Indeed, light may propagate within the semiconductor layer 104 between first and second major surfaces thereof in one or more waveguide modes (as opposed to light scattering). Additionally or alternatively, light may propagate within the composite structure of the substrate 102 and the semiconductor layer 104 in one or more waveguide modes. The light propagation in one or more waveguide modes is not the same as light scattering or trapping (of the prior art). In light scattering or trapping the light reflects off of a discontinuity at respective distributions of angles (which results in the escape of significant light energy from the cell). In contrast, light propagation in one or more waveguide modes exhibits the characteristic of substantially total internal reflection and the escape of very little or no light energy.

It is understood that the structural and electrical details of the photo-sensitive p-n junction 106 are relatively complex, but are very well known and understood in the art. Thus, for the sake of brevity and clarity, such details (including formation techniques, location of electrical conductors, etc.) will be omitted from this description. It is noted, however, that in solar-cell technologies, p-n junctions are formed in semiconductor materials to convert solar radiation into electrical current. These p-n junctions separate the electron-hole pairs created by the absorption of radiation to generate useful electrical current for an external load. Depending on the semiconductor material and process used, various type of solar-cell designs have been developed in the art. Some are simple p-n junctions, while others are more complex and are optimized for higher efficiency. Such more complicated junctions include p-i-n junctions. In some cases, p+ and n+ layers are added to the p-n and/or p-i-n junctions for improved charge collection and electrode/solar cell fabrication. In this application, when a p-n junction is referred to, it may include any of the various junctions indicated above, others known from existing literature, and/or those developed hereafter.

As illustrated by the dashed arrows in FIG. 2, incident solar energy (light) may enter the substrate 102, specifically through a side surface or one of the major surfaces 108, 110, as depicted by light ray A. Depending on the angle of the light ray A, a light ray A′ will reflect off of the discontinuity between the substrate 102 and the semiconductor 104 at an angle, and a light ray B will enter the semiconductor layer 104 at a particular angle. The light ray B will reflect off of a far major surface of the semiconductor layer 104 as ray B′. Without any scattering structures, the ray B′ will have the characteristic of a total internal reflection of ray B. (The light ray A′ will reflect off of the major surface 110 back toward the semiconductor layer 104 and the propagation pattern will continue.) Depending on the angle of the light ray B′, the light will either escape the semiconductor layer 104 as light ray C, or propagate in a direction parallel to the major surfaces of the semiconductor layer 104 in a waveguide mode, as illustrated by rays B, B′, B″, etc. As will be discussed later herein, the photovoltaic device 100 may include a light directing feature that is operable to cause the incident light ray (or rays) A to propagate through the substrate 102 and into the semiconductor layer 104 at or above a critical angle such that the waveguide action results in light rays B, B′, B″, etc. The waveguide action arises from the angle of the light rays (as discussed above) and respective dielectric constant discontinuities proximate to the first and second major surfaces of the semiconductor layer 104. Thus, as the incident light reflects a plurality of times between the first and second major surfaces of the semiconductor layer 104, the solar energy thereof impinges upon the p-n junction 106 a plurality of times.

For any light rays that were not initially coupled into the semiconductor layer 104, such as ray A′, or any light rays leaving the semiconductor layer 104 and entering the substrate 102, such as ray C, such rays may reflect off of the major surface 110 of the substrate and back to the semiconductor layer 104, such as ray D. It is desirable to design the structure such that rays that were not initially coupled into the semiconductor layer 104, such as ray A′, or other light rays, such as ray C, reflect off of the interface of surface 110 with total internal reflection. Thus, depending on the angles of reflection, such light may re-enter the semiconductor layer 104 and propagate therein in the waveguide mode discussed above.

As noted above, light may alternatively or additionally propagate within the composite structure of the substrate 102 and the semiconductor layer 104 in one or more further waveguide modes. This characteristic is achieved when the light rays, such as ray D, propagates through the substrate 102 and into the semiconductor layer 104 at or above a critical angle such that rays E, E′, D′, D″ result in further rays E″, E′″, etc.

The above reflection action of the light impinging upon the p-n junction 106 numerous times has the advantageous effect of significantly increasing the efficiency of the photovoltaic device 100 over conventional techniques. Indeed, the photovoltaic device 100 may be considered to be in vertical waveguide configuration, which increases the absorption path length for high efficiency and small form factors. This is so because the light penetrates into the semiconductor layer 104 and is partially absorbed on each reflection and consequently generates more electron-hole pairs. With multiple reflections, the radiation can be very efficiently absorbed. In essence, this approach decouples a previously accepted limiting relationship between the semiconductor layer thickness and the solar light absorption. Thus, very efficient light absorption, of even the infrared spectrum, is obtained in thin-film construction. Consequently lower cost thin-film fabrication of solar cells may be achieved without compromising cell efficiency.

A principle of this approach is that the light focused and guided in the substrate 102 bounces on and reflects through the p-n junction 106 several times depending on the incident angle and thickness of the substrate 102, and the properties of the semiconductor layer 104, use of light guiding materials/structures, etc. On each impingement, solar radiation crosses the active solar cell and becomes absorbed, generating electron-hole pairs. Within a few millimeters of propagation (in a direction parallel to the major surfaces 108, 110) within the semiconductor layer 104, the light can bounce several times and the effective path length of the solar light in the active medium is increased. The path length can be approximated by the following formula:

(path)/(number of reflections)˜2*t/sin(theta),

where theta is the internal angle of the radiation in the active semiconductor layer 104, and t is the thickness of the active semiconductor layer 104. Even for a substrate height of a few millimeters, the effective path length through the active semiconductor layer 104 can be significant multiples of the active semiconductor layer 104 thickness and can lead to complete or near complete absorption of the solar radiation including the long wavelengths.

The above reflection action of the light impinging upon the p-n junction 106 numerous times has the advantageous effect of significantly increasing the efficiency of the photovoltaic device 100 over conventional techniques. This is so even when the semiconductor layer 104 is of thin-film construction, such as being less than about 1 um thick. As generally accepted in the art, thin-film and thick-film solar cells are defined by the process and physical thickness of the active semiconductor layers used in the solar cells. In the context of the waveguide solar cells disclosed in this application, the cells are differentiated based on the absorption of the solar radiation of interest in a single pass. Solar radiation at ground level consists of a range of wavelengths from UV to near infrared.

Depending on the semiconductor material 104 used and its band gap, there is a wavelength range covered by the solar cell. The absorption coefficient varies from a very large value to a small value as a function of solar wavelength, particularly near the band edge. For example, for single crystal silicon, the wavelength range of interest is from around 350 nm to about 1100 nm. The absorption coefficient for single crystal silicon at 400 nm is about 8.89E+04 cm-1. In contrast, the absorption coefficient for single crystal silicon at 900 nm is only 2.15E+02 cm-1. If 900 nm radiation falls on a 1 um (0.0001 cm) thick single crystal silicon solar cell, only about 2% of the radiation is absorbed in a single pass through such a cell, whereas almost 99% of the light is absorbed at 400 nm. In this case, a 1 um thickness cell would not be able to absorb a majority of the radiation at 900 nm in a single pass and can be considered as too thin for single pass geometries. Such a solar cell is considered a “thin-film”solar cell in the context of the waveguide solar cells being disclosed here. Silicon thicknesses of about 100-200 um are needed to absorb a majority of the radiation up to 1100 nm in a single pass and cells with such thickness are considered “thick-film” solar cells in this context.

In one or more embodiments herein, the semiconductor material of the layer 104 may be in the form of amorphous, micro- or nano-crystalline, polycrystalline, or substantially single-crystal material. The term “substantially” is used in describing the layer 104 to take account of the fact that semiconductor materials normally contain at least some internal or surface defects either inherently or purposely added, such as lattice defects or a few grain boundaries. The term substantially also reflects the fact that certain dopants may distort or otherwise affect the crystal structure of the semiconductor material. For the purposes of discussion, it may be assumed that the semiconductor layer 104 is formed from silicon. The above features (and those described later herein) may be applied using other inorganic semiconductor materials such as the type III-V GaAs, copper indium gallium diselenide, InP, etc. Still other semiconductor materials may be employed, such as the IV-IV (i.e. SiGe, SiC), the elemental (i.e. Ge), or the II-VI (i.e. ZnO, ZnTe, etc.). Thin Film organic semiconductors can also be employed with proper consideration.

The substantially transparent substrate 102 may be formed from glass, glass-ceramic, polymers, etc. For example, the substrate 102 may be formed from an oxide glass or an oxide glass-ceramic, such as glass substrates containing alkaline-earth ions. The glass may be silica-based, such as, substrates made of CORNING INCORPORATED GLASS COMPOSITION NO. 1737 or CORNING INCORPORATED GLASS COMPOSITION NO. EAGLE 2000®.

When the semiconductor layer 104 is, for example, silicon and the substrate 102 is formed of a glass or glass ceramic material, then the semiconductor layer 104 may be bonded to the substrate 102 using any of the existing techniques. Among the suitable techniques is bonding using an anodic bonding process. A suitable anodic bonding process is described in U.S. Pat. No. 7,176,528, the entire disclosure of which is hereby incorporated by reference.

A tiled approach may also be employed, where multiple semiconductor layers 104 are disposed on one or more of the major surfaces of the substrate 102 in spaced apart relation. In such a configuration the respective electrodes are coupled in parallel and/or series to achieve the desired voltage and current magnitudes.

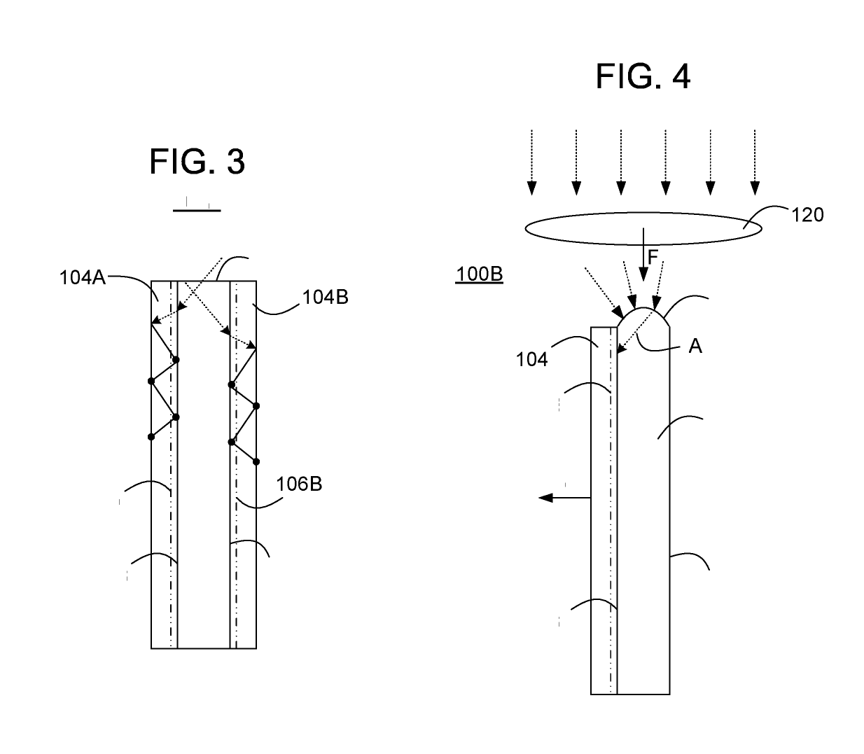

With reference to FIG. 3, which is a side view of an alternative photovoltaic device 100A, variations in the structural characteristics of the device may be made to further improve the conversion of light energy into electrical power. The photovoltaic device 100A is of similar construction as the photovoltaic device 100 of FIG. 2, however, the device 100A includes at least two thin-film semiconductor layers 104A, 104B, at least one such layer 104 coupled to each of the first and second major surfaces 108, 110 of the substrate 102, and each layer 104 including at least one photo-sensitive p-n junction 106A, 106B. Under this configuration, the waveguide characteristic of the composite waveguide structure is operable to cause the waveguide action within each of the semiconductor layers 104A, 104B and the reflection of the light to impinge upon the respective p-n junctions 106A, 106B of each of the thin-film semiconductor layers 104A, 104B a plurality of times.

The illustrated light propagation in each of the semiconductor layers 104A, 104B has been simplified for purposes of discussion. It is noted, however, that the waveguiding action within the semiconductor layers 104A, 104B alone or within one or more composite structures may be achieved (as was discussed with respect to FIG. 2). In the illustrated embodiment of FIG. 3, one example of a composite structure is the combination of the substrate 102 and the semiconductor layer 104A (where waveguiding would occur through the composite structure as discussed with respect to FIG. 2—rays C, D, E, E′, D′, D″ E″, E′″, etc.). Alternatively or additionally another composite structure may be the combination of the substrate 102 and the semiconductor layer 104B, where again the waveguiding would occur through the composite structure. A further example of a composite structure would include the substrate 102 and both semiconductor layer 104A, 104B. In such a case, the waveguide mode propagation may include: (i) a ray directed from the substrate 102 into the semiconductor layer 104A, (ii) a reflected ray directed from the semiconductor layer 104A into the substrate 102 and further into the semiconductor layer 104B, (iii) a reflected ray directed from the semiconductor layer 104B into the substrate 102 and further into the semiconductor layer 104A, and (iv) repeating.

Reference is now made to FIG. 4, which is a side view of a further photovoltaic device 100B in accordance with one or more further aspects of the present invention. The illustrated light propagation in the structure 100B has been simplified to avoid repetition, however, the waveguiding action within the semiconductor layer 104 (and/or composite structure) may be achieved as was discussed with respect to FIG. 2. In the illustrated embodiment, additional optical mechanisms may be employed to enhance the absorption of solar energy and electrical power generation. For example, one or more lenses, prisms, reflectors, scattering surfaces, etc. that redirect the solar radiation for improved waveguide action and light trapping may be employed. Additionally, the concentrator optics may be transmissive, reflective or diffractive, and may be of imaging or non-imaging construction.

More specifically, the photovoltaic device 100B may include a light collecting device that is operable to direct solar light toward one of the plurality of side surfaces of the substrate 102 such that the solar light is coupled into the substrate 102 in the waveguide mode. The light collecting device may be a solar concentrator 120 having a focal axis F directed toward the one of the plurality of side surfaces of the substrate 102. Notably, the focal axis F is transverse to a normal axis N of the photovoltaic device 100B (and may be close to perpendicular thereto).

Alternatively, or additionally, the light collecting device may include a convex edge 122 characteristic of one or more of the side surfaces of the substrate 102. The curvate characteristic of the edge 122 will tend to improve the collection of light into the waveguide mode, either alone or in combination with the concentrator 120.

The composite waveguide includes the transparent substrate 102, and the semiconductor layer 104. In addition, the composite waveguide can include various other intermediate layers that serve various other functions. For example, the composite waveguide can contain one or more transparent conductor layers or other dielectric layers in between the substrate 102 and the semiconductor layer 104. These layers can serve the function of charge collecting electrodes and/or antireflection coatings or bonding agents.

The intermediate layers or other layers may advantageously include the option of putting selective scattering/diffractive features in optimal locations as opposed to the entire illuminated p-n junction surface as in prior art. The scattering/diffractive features are employed to further induce waveguiding within the semiconductor layer 104. They can also operate to facilitate additional light trapping. One of the constraints on the intermediate layers of the composite waveguide is that they should not introduce unnecessary losses and they should facilitate as much of the absorption as possible in the p-n junction 106 for maximum efficiency.

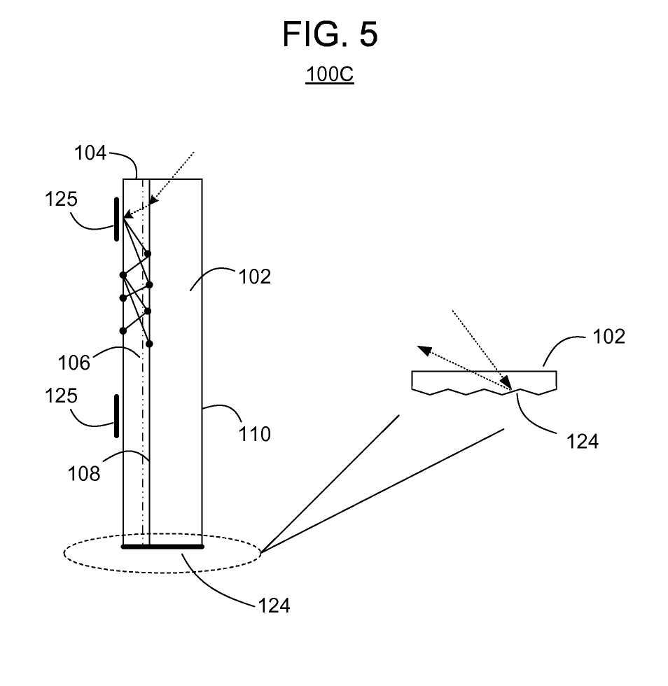

FIG. 5 is a side view of a further photovoltaic device 100C in accordance with one or more further aspects of the present invention. To amplify the aforementioned increase in the absorption path length and/or to reduce the height of the active semiconductor layer 104 (the vertical dimension in FIG. 5) for lower cost, the light that reaches the side surface at the bottom of the substrate 102 may be reflected or scattered using a light reflective element 124. The expanded view of the light reflective element 124 in FIG. 5 reveals that at least one light reflective element 124 is dispose proximate to at least one of the plurality of side surfaces (e.g., the bottom side surface) of the substrate 102. The light reflective element 124 is operable to cause the light that has reflected a plurality of times between the first and second major surfaces 108, 110 in the waveguide mode to reverse or redirect its propagation direction and reflect a further plurality of times between the first and second major surfaces 108, 110 in a waveguide mode and to impinge upon the p-n junction a further plurality of times. Although the light reflective element may take on many forms, one example is a prismatic structure (scattering) structure. Other forms may include lenses, prisms, reflectors, scattering surfaces, diffractive surfaces, etc. The length of the panel may be on the order of 10s of centimeters and absorb all or nearly all the available solar radiation.

It is preferable to redirect the light along the long dimension of the substrate 102 and also to be within the numerical aperture of the composite waveguide. Prismatic and diffractive features may be better able to do that compared to random scattering structures. The objective of these structures is to redirect the light to increase the effective absorption in the p-n junctions and not to re-scatter out of the composite waveguide solar cell.

Generally, the thickness of the semiconductor layer 104 is in the range of about 1-10 um, whereas the thickness of the substrate 102 is on the order of 100s of microns. The refractive indices of the substrate 102 and semiconductor layer 104 are such that the distance between the bounces of the waveguide rays of the structure are determined by the formula discussed above. The height of the substrate 102 should be between a few millimeters to a couple of centimeters in order to achieve a substantial number of bounces and resultant high light absorption in the p-n junctions 106. The absorption may be substantially improved when the light is waveguided within a semiconductor layer 104 of the 1-2 um. In such case, each bounce takes only a few microns and the height of the substrate 102 need only be a few tens to a few hundreds of microns to achieve a significant number of bounces and high absorption.

FIG. 5. illustrates that placing selective diffractive or selective scattering features 125 close to the entry facet (in this case near the top edge of the composite waveguide structure 100C) facilitates the waveguiding within the semiconductor layer 104. After the first entry into semiconductor layer 104, when the light ray is redirected by the diffractive/selective scattering surface 125 into a shallower angle (which is greater than the critical angle dictated by the refractive indices of the substrate 102 and the semiconductor layer 104), the ray will not re-enter the substrate 102. Instead, the light ray will totally internally reflect within the semiconductor layer 104 and waveguiding is achieved. For the waveguiding to commence and not re-scatter, the scattering feature 125 should be in bands that are only a few microns wide with a few tens of microns wide gaps near the entry point. With a silicon layer 104 bonded to the substrate 102, the outside surface of the silicon layer 104 is accessible for such patterning before further processing. The diffractive or scattering features may be alternatively or additionally placed on additional transparent dielectric or passivation layers.

With reference to FIG. 2, in order to reduce the total height required for the substrate 102, scattering may be added, for example, at the air/substrate interface at major surface 110. This scattering may be present along the entire length of surface 110 or only some fraction of the length beginning at an edge where light is incident and extending toward an opposite edge. This may eliminate the need to provide a light redirecting surface at 124 (FIG. 5) and may be simpler to implement than processing the very thin edge of 124.

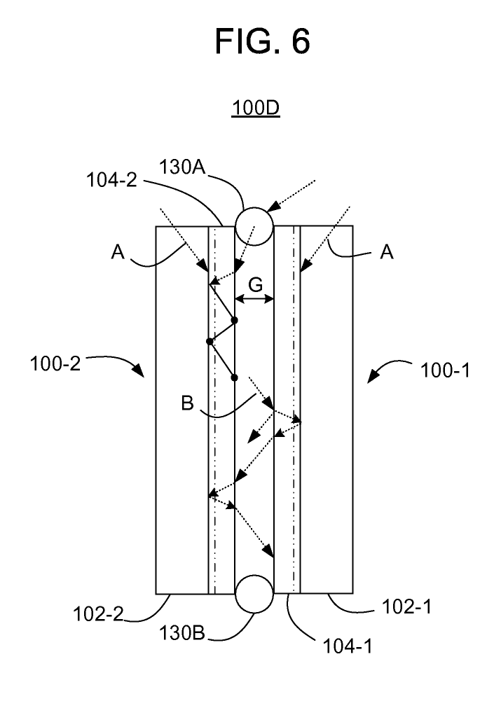

FIG. 6 is a side view of a further photovoltaic device 100D in accordance with one or more further aspects of the present invention. In this embodiment, at least a pair of photovoltaic devices 100-1, 100-2, each of substantially the same construction as the photovoltaic device 100 of FIG. 2, are employed. Again, the illustrated light propagation in the structure 100D has been simplified to avoid repetition, however, the waveguiding action within the semiconductor layer 104-1, the semiconductor layer 104-2 (and/or composite structures) may be achieved as was discussed with respect to FIG. 2. At least first and second semiconductor layers 104-1, 104-2 are disposed facing one another in a spaced apart configuration forming a gap G therebetween. The gap is formed via respective rods 130A, 130B. The rods 130A, 130B disposed in the gap G may be operable to space the first and second semiconductor layers 104A, 104B apart and/or focus at least some solar light into the gap G such that the light propagates in a waveguide mode along the gap impinging upon the respective p-n junctions a plurality of times. The gap volume may be filled with high index material, or may be filled with a gas or fluid, such as air. Thus, in addition to obtaining multiple reflections within each semiconductor layer 104 via light entering through edges of the respective substrates 102, the incident light will enter the gap, thereby further entering the semiconductor layers 104, waveguiding therein, and impinging upon the respective p-n junctions a plurality of times. This results in increased absorption even with thin semiconductor layers 104 of about 0.5-1.0 um. The gap may be between about 0.1-0.7 mm.

Turning again to the various aspects of the light propagation within the device 100D, a composite structure may be defined to include the two semiconductor layers 104-1, 104-2 and the gap G. In such an example, light propagation in one or more waveguide modes may be defined by: a ray B directed from the gap G into the semiconductor layer 104-1 (a reflective ray may also bounce back into the gap initiating further propagation modes), (ii) a reflected ray directed from the semiconductor layer 104-1 back into the gap G and further into the semiconductor layer 104-2, (iii) a reflected ray directed from the semiconductor layer 104-2 back into the gap G and further into the semiconductor layer 104-1, etc.

Those skilled in the art will appreciate from the foregoing that other composite structures may be defined within the device 100D, such as at least one of: (i) the first substrate 102-1 and the first semiconductor layer 104-1; (ii) the second substrate 102-2 and the second semiconductor layer 104-2; (iii) the gap G and the first semiconductor layer 104-1; (iv) the gap G and the second semiconductor layer 104-2; (v) the gap G and the first and second semiconductor layers 104-1, 104-2; and (vi) combinations of the above.

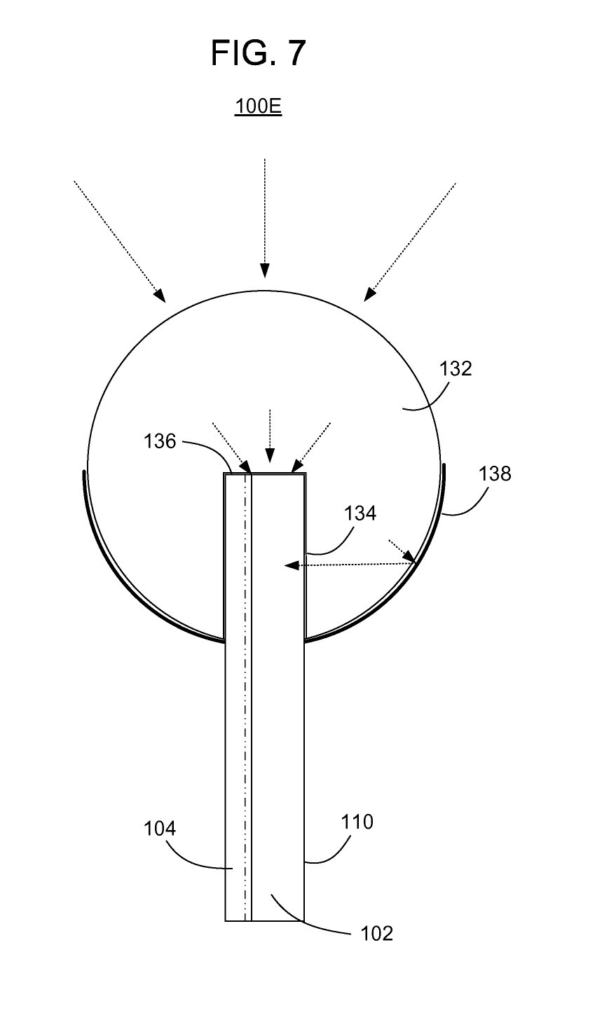

FIG. 7 is a side view of a further photovoltaic device 100E in accordance with one or more further aspects of the present invention. The combination substrate 102 and semiconductor layer 104 may be any suitable ones of the aforementioned configurations or those later described herein. The photovoltaic device 100E further includes a light collecting device 132 operable to direct solar light toward one of the plurality of side surfaces of the substrate 102 such that the solar light is coupled into the substrate 102 and then into the semiconductor layer 104 in the waveguide mode. By way of example, the light collecting device 132 includes a substantially cylindrical rod having a longitudinal slot 134 extending along a wall thereof. The substrate 102 and semiconductor layer 104 are located within the slot 134 such that one of the plurality of side surfaces of the substrate 102 abuts a bottom 136 of the slot 134. The slot 134 is shown in exaggerated form (showing a gap with the substrate 102 and layer 104) although in a practical device a snug fit is preferred.

A depth of the slot 134 is such that the substrate 102 and layer 104 are positioned at an appropriate distance from the top of the rod 132 for optimum light collection. In this regard, the rod 132 includes optical properties that cause the solar light to couple into the substrate 102 in the waveguide mode. For example, the rod 132 may be of the tracking or non-tracking type concentrator variety, where the material of the rod 132 may be a high index (hence high NA) material, such as glass, transparent polymer, and/or plexiglass. The rod 132 may be shaped for better packing array and for reducing aberrations. Alternatively or additionally, portions of the surface of the rod 132 may be modified for further optical properties that cause the solar light to couple into one of the major surfaces of the substrate 102. For example, element 138 may be roughening, grooving, coating, (reflective and/or scattering), etc. for redirecting and trapping the light. This may cause light that would otherwise leave the rod 132 to redirect toward the substrate 102 and layer 104. Alternatively or additionally, the element 138 may include one or more reflectors located proximate to an outside surface of the rod 132, which direct light exiting the wall of the rod 132 back toward the substrate 102 and semiconductor layer 104. A number of the rod concentrators 132 may be stacked side by side for scaling up over an area.

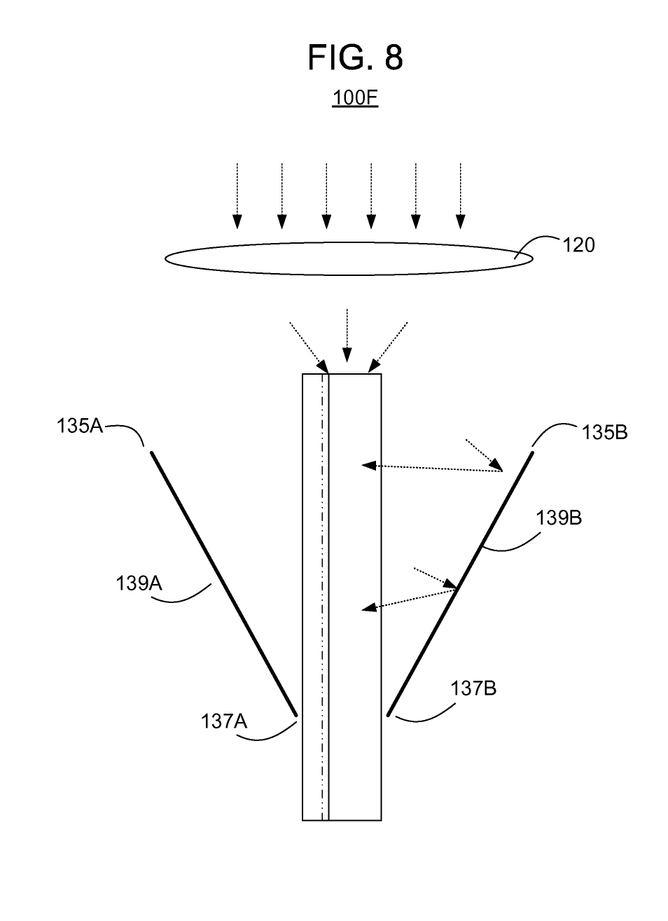

One or more further reflectors 139A, 139B (FIG. 8), which are secondary tapered concentrators, may also be employed alone or in combination with the rod 132 and/or the concentrator 120 to form a further embodiment 100F. The secondary tapered concentrators 139A, 139B may be employed to collect light not focused onto the substrate 102 and trapped. This is especially desirable with non-tracking concentrators 132. The reflectors 139A, 139B may include 1-D refractive or reflective tapers and/or light funnels with light trapping structures. They can be corrugated 1-D linear or parabolic light funnels for light weight with diffractive or refractive focusing elements. The inside surfaces tapers may be coated with highly reflective coatings or dielectric mirrors. Such designs would be suitable for low concentration factors.

The reflectors 139A, 139B each include a first edge 137A, 137B, located proximate to the substrate 102 and semiconductor layer 104. The reflectors 139A, 139B angle away from the respective first edges 137A, 137B toward respective opposite edges 135A, 135B. This arrangement operates such that the reflectors 139A, 139B cause the light to reflect back toward the substrate 102 and semiconductor layer 104 and to couple into one of the major surfaces 108, 110 of the substrate 102.

The long axis of the cylindrical lens may be oriented the East-West direction so that the long length of the rod 132 allows the capture of the solar radiation as the sun moves over the horizon during the day. For low concentration designs, the high NA of the rod 132 may capture the radiation without significant efficiency reduction even if the illumination is not on axis during the seasonal changes of sun's position on the horizon.

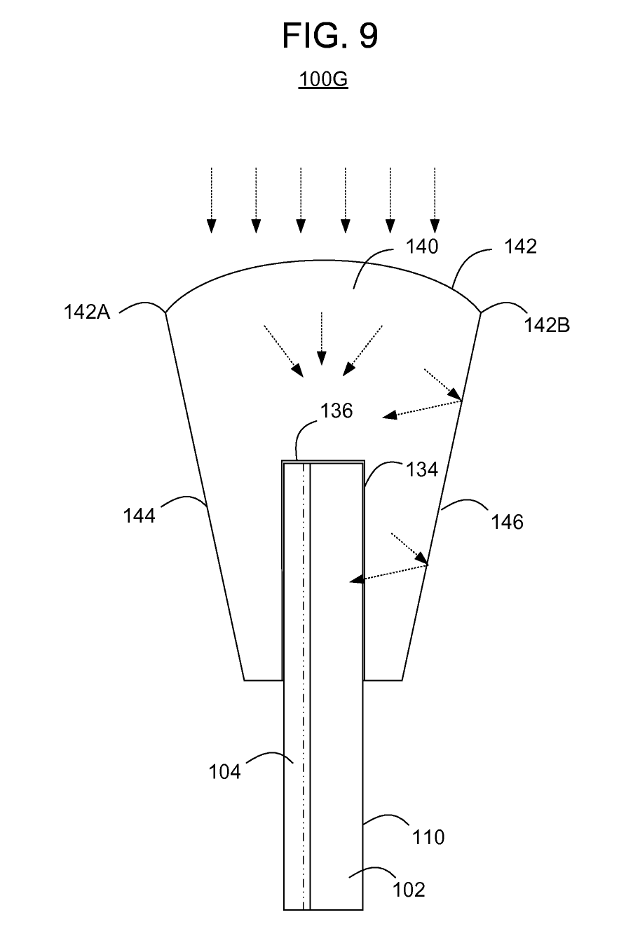

FIG. 9 is a side view of a further photovoltaic device 100G in accordance with one or more further aspects of the present invention. In this embodiment, a light collecting device 140 includes refractive, focusing and tapered concentrators combined in a monolithic fashion. In particular, the light collecting device 140 includes a wedge-shaped rod having a longitudinal slot 134 extending along a narrow edge thereof. The substrate 102 and semiconductor layer 104 is located within the slot 134 such that one of the plurality of side surfaces of the substrate 102 abuts a bottom 136 of the slot 134. The wedge-shaped rod 140 may be made using transparent polymer or glass materials. Plexiglass or polymer materials may provide lower cost, easier shaping, and lighter weight; however, they may not be as durable and may have absorption of the shorter wavelengths of solar radiation. Glass may be potentially more durable, and have lower UV or blue absorption but it can be more difficult to shape, and can be costly for high index material.

The wedge-shaped rod 140 includes optical properties that cause the solar light to be directed toward the one of the plurality of side surfaces of the substrate 102 and to direct light that would otherwise not couple into the substrate 102 back toward the substrate 102 and semiconductor layer 104. The wedge-shaped rod 140 may includes a convex domed surface 142 opposite the slot 134 defining a focal axis directed toward the side surface of the substrate 102. The wedge-shaped rod 140 includes at least one side surface, and preferably a pair of surfaces 144, 146 that extend from the narrow edge or end of the rod 140 outward and angled away from the substrate 102 and semiconductor layer 104 toward respective edges 142A, 142B of the convex domed surface 142. The respective side surfaces 144, 146 are operable to direct light that would otherwise not couple into the substrate 102 back toward the substrate 102 and the semiconductor layer 104, such as to couple into one of the major surfaces 108, 110 of the substrate 102. The side surfaces 144, 146 may be diffractive to focus the light in desired directions.

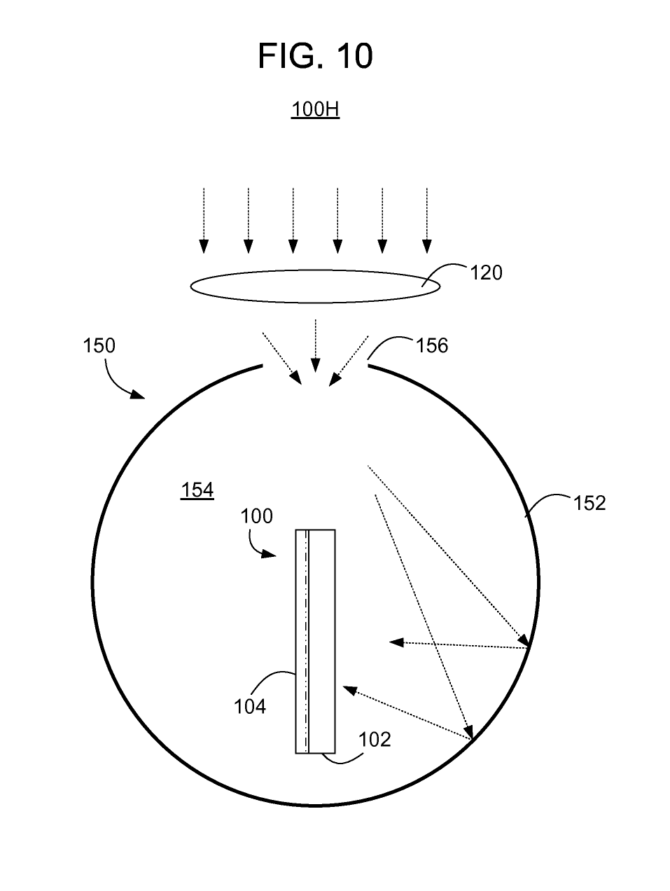

FIG. 10 is a side view of a further photovoltaic device 100H in accordance with one or more further aspects of the present invention. The combination substrate 102 and semiconductor layer 104 may be any suitable ones of the aforementioned configurations or those later described herein, the illustrated structure being the basic photovoltaic device 100 of FIG. 2. The photovoltaic device 100H further includes a light collecting device 150 operable to direct solar light toward one of the plurality of side surfaces of the substrate 102 such that the solar light is coupled into the substrate 102 and into the semiconductor layer 104 in the waveguide mode.

By way of example, the light collecting device 150 includes an integrating-type hollow cylinder having a cylindrical wall 152 defining an interior volume 154. The substrate 102 and the thin-film semiconductor layer 104 are located at least partially within the interior volume 154. The cylindrical wall 152 includes a slot 156 extending longitudinally, defining an aperture for the solar light to enter the interior volume 154. The cylindrical wall 152 includes a reflective interior surface that may direct the light toward one of the plurality of side surfaces of the substrate 102 such that the solar light is coupled into the substrate 102 in the waveguide mode. Alternatively or additionally, the reflective interior surface of the wall 152 may direct the light back toward the substrate 102 and semiconductor layer 104 and to couple into one of the major surfaces 108, 110 of the substrate 102.

The slot 156 is operable to allow for the focal spot movement during the course of the day, which would allow non-tracking solar panels without significant reduction in efficiency. Additionally, the photovoltaic device 100H may further include a solar concentrator 120 as previously discussed herein to direct light into the slot 156.

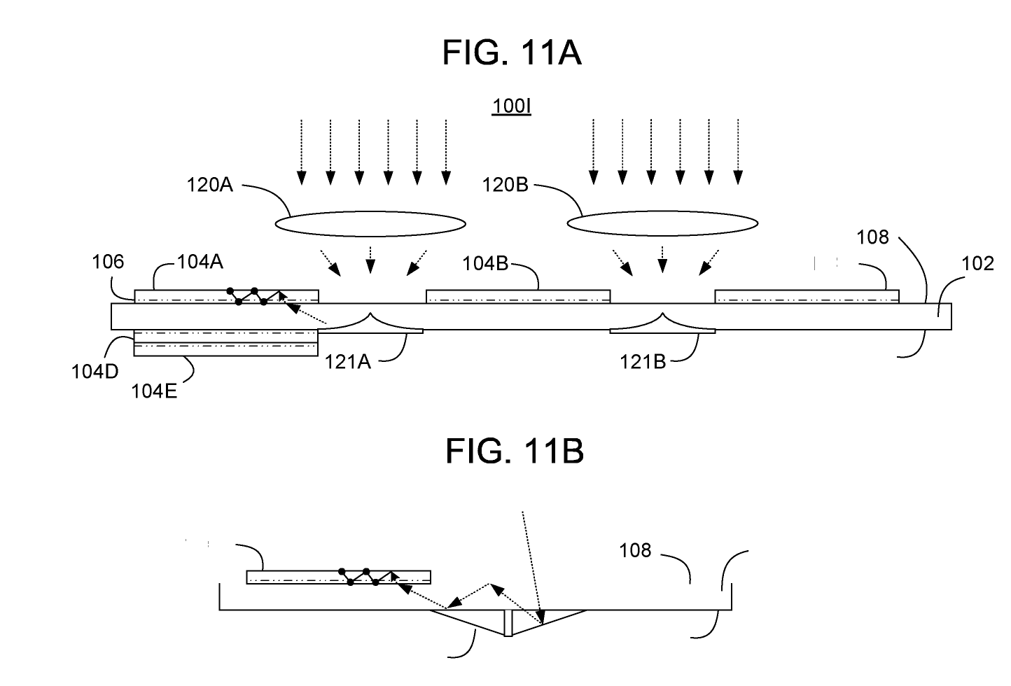

FIG. 11A is a side view of a further photovoltaic device 100I in accordance with one or more further aspects of the present invention. This embodiment is a variation of the waveguiding and trapping geometry, where the photovoltaic device is in a horizontal orientation rather than a vertical orientation. The photovoltaic device 100I includes a substrate 102 having first and second major surfaces 108, 110 and a plurality of side surfaces. One or more semiconductor layers 104A, 104B, 104C, are coupled to the first major surface 108 of the substrate 102 and include at least one photo-sensitive p-n junction 106.

It is noted that this embodiment (as well as the other embodiments of the invention discussed above) may support one or more p-n junctions 106. These junctions can be of homogeneous or heterogeneous type. The semiconductor layer 104 may be selected to cover a broad range of wavelengths for efficient usage of all of the solar spectrum. For example, single crystal silicon may be used with amorphous silicon, Si—Ge, Ge, GaAs, etc. The single crystal silicon may also be combined with polymer semiconductors. This approach provides an advantage in any solar cell where the semiconductor layer 104 has insufficient absorption in a single pass.

As illustrated in FIG. 11A, the semiconductor layer 104 may include a stacked, multi-junction configuration 104D, 104E or the semiconductor layer 104 may be spatially separated 104A, 104B, 104C.

A light collecting device of the structure 101I includes one or more solar concentrators 120A, 120B, each having a focal axis F operable to direct solar light toward the first major surface 108 of the substrate 102. The light entry areas on the surface 108 of the substrate 102 may include AR coatings to collect light at different angles of incidence and different spectrums. The light collecting device also includes one or more corresponding reflective elements 121A, 121B operable to direct the light entering the substrate 102 through the first major surface 108 transversely with respect to the focal axis of the solar concentrators 120A, 120B such that the solar light is coupled into the semiconductor layers 104 in a waveguide mode.

As with some of the other embodiments discussed above, the illustrated light propagation in the structure 100I has been simplified to avoid repetition, however, the waveguiding action within any of the semiconductor layers 104 and/or any of numerous composite structures may be achieved as was discussed above.

The horizontal waveguide configuration 101I may be implemented in several embodiments. In the embodiment of FIG. 11A, the light redirecting element 121 is built into the substrate 102. This may be a shaped reflective/diffractive cavity.

It may be more advantageous, and the substrate strength may be better maintained, if an alternative, shaped cavity is employed. In this alternative, a shaped “redrawn cane” of suitable material is attached to the bottom of the substrate 102 at suitable locations. For example, as shown in FIG. 11B, a prismatic cane 123 may be drawn from a large glass blank, shaped into a prism and heated to redraw to a final dimension of about 1-2 mms. Low cost techniques similar to fiber redrawing technologies may be used to produce the redirecting structures. The outside facets of the prism 123 may be coated with metal or dielectric reflective coatings in a batch process. The size and facet angles of the redirecting prism 123 may be designed based on the parameters of the substrate 102, the concentrator lens 120 parameters, and the seasonal variation of the sun's movement over the horizon, etc. Depending on which side of the redirecting prism 123 facet the solar radiation is focused, the light would be redirected to the left or right side toward the semiconductor layers 104. This is an advantage in collecting the radiation and maintaining the efficiency even with seasonal variations of the sun's movement over the horizon.

The advantages of the horizontal composite waveguide solar cells structure 101I include:

Scalability to large panels. The substrates 102 may be quite large and the semiconductor layer 104 may be either bonded or deposited in long length with a few mms or cms width with 1-2 mm gaps (FIG. 11A).
Reduced height compared to the vertical waveguide configuration. This form factor advantage may be important in some of roof-top applications where previously concentrator designs were not considered practical.
Potentially lower assembly and processing cost as the horizontal approach does not involve cutting or wire sawing large panels into 5-10 mm high strips as would be involved in the vertical design of FIG. 2.

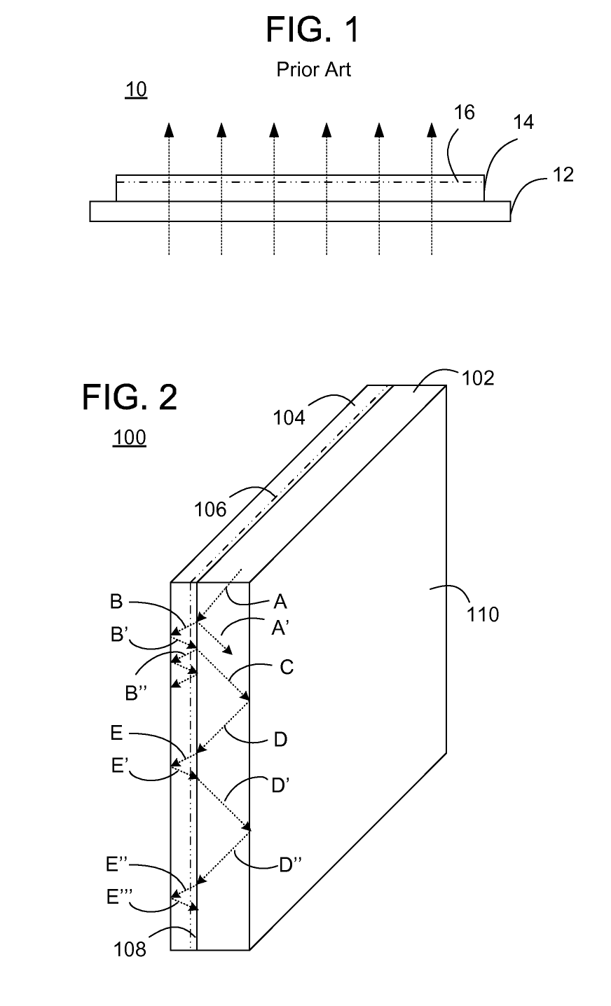

It may be easier to incorporate some of the AR coating and electrical interconnections steps in this geometry. A distinguishing feature of the composite waveguide approach compared to conventional light trapping structures is the separation of the light entry locations from the light waveguiding regions of the solar cell. In the prior art substrate (or superstrate) configurations (e.g., FIG. 1), the light falls across the entire active surface of the solar cell. If employed, the light trapping/scattering features need to be disposed across the entire active surface. If any sections do not have such features, the light incident on those areas will not scatter and will have only a single pass through the p-n junction. Also, any light that is trapped in one area may re-scatter out of the solar cell by the scattering features in adjacent areas.

In contrast, the light entry and waveguiding sections are separated in one or more of the embodiments herein. For example, in FIG. 2, the entry point for the light is the edge facet of the composite waveguide (top edge of the substrate 102) and the active p-n junction surface is separated from this facet and is orthogonal to it. Similarly, in FIG. 11A, the light entry surface and active p-n junction surfaces are separated. The light entry is facilitated by the redirecting optics 121 into the composite waveguide. This can be combined with low concentration optics, such as 120, shown in FIG. 4. This approach provides a number of advantages over the prior art. A significant advantage is the fact that the light trapping is not dependent on the scattering features. This eliminates the re-scattering problem present in the prior art designs. The approach also provides flexibility in the p-n junction placement. For example, p-n junctions can be fabricated on both sides of the transparent substrates as shown in FIG. 3. The composite waveguide approach also provides the flexibility in placing the scattering, diffractive surfaces in only selective locations to further improve the waveguiding within the semiconductor layer without the concern about re-scattering. Since the semiconductor layer is only 1-2 um generally, waveguiding within that layer rather than the entire substrate composite waveguide would lead to light absorption within 100-200 um rather than several mms otherwise required. (As was explained with reference to FIG. 5.) Additionally, since the entry facet does not include the very high index semiconductor layer, it is easier to design the AR coatings for the entry facet of the transparent substrate, which is generally a lower index glass or polymer. This allows a better optimization over a broader wavelength and angular range.

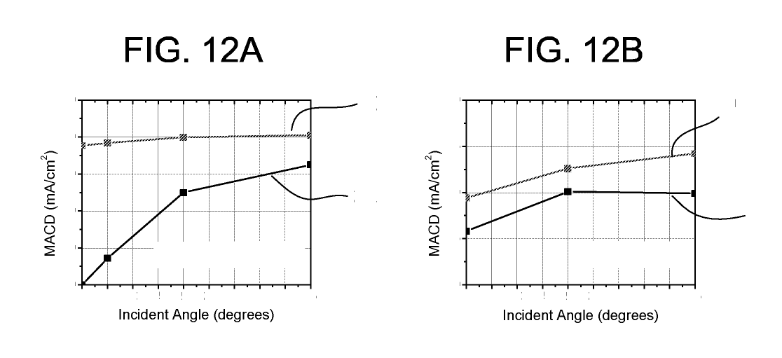

FIG. 12A, 12B are graphs illustrating simulation results of certain parameters of merit associated with a basic operational concept of the photovoltaic devices of the present invention. The results show the maximum achievable current density (MACD) versus incident angle at the top surface of the cell without concentrator optics in the configuration of FIGS. 2 and 3. These results indicate that the photovoltaic structures described herein are operable to absorb a significant amount of solar light, including the long wavelengths, even for semiconductor layer thicknesses of less than about 1 um and vertical heights as small as about 2 mm. For the wavelength range considered in the model of 300-1200 nm, the maximum MACD value is 45.9 mA/cm². Values above 30 mA/cm² are considered good and above 35 mA/cm² are considered very good. The horizontal axes on the graphs of FIGS. 12A and 12B indicate the incident angle on the edge surface of the substrate 102 (e.g., see FIG. 2). The range of angles between 0 and 45 degrees represent the angle associated with a potential concentrator 120, such as shown in FIG. 4. FIG. 12A illustrates the performance (line 202) of a planar reflector and the performance (line 204) of a Lambertian reflector located at 124 of FIG. 5. This simulation is for the case of a 0.7 mm wide and 10 mm tall substrate 102. The semiconductor material 104 is a 1 um thick silicon layer. FIG. 12B shows the difference between single side structure 100 (line 206) and double side structure 100A (line 208). This simulation is for the case of a 0.7 mm wide and 2 mm tall substrate 102 and a Lambertian reflector at 124 of FIG. 5. The device performance is a strong function of the width of the substrate 102. For narrow substrates 102, less height is required for very good performance compared with wider substrates. Devices with a substrate thickness of 0.2 mm and glass height of 5.0 mm have MACD values in excess of 40 mA/cm². The model does not take into consideration several potential loss mechanisms, including highly doped silicon loss, contact shadowing loss, and metal contact absorption loss.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

What is claimed is:

1. A photovoltaic device, comprising:
a substantially transparent substrate having first and second major surfaces and a plurality of side surfaces;
a thin-film semiconductor layer having first and second major surfaces, being coupled to the first major surface of the substrate, and including first and second major surfaces and at least one photo-sensitive p-n junction therein; and
a light directing feature operable to cause incident light to propagate through the substrate and into the semiconductor layer in a waveguide mode such that the light reflects a plurality of times between the first and second major surfaces of the semiconductor layer and impinges upon the p-n junction a plurality of times.

2. The photovoltaic device of claim 1, wherein the light directing feature is operable to cause incident light to propagate through at least one composite structure of the device in a waveguide mode, wherein the composite structure includes the substrate and the semiconductor layer.

3. The photovoltaic device of claim 1, wherein a thickness of the semiconductor layer is less than about 2 um.

4. The photovoltaic device of claim 1, wherein the substantially transparent substrate is formed from at least one of glass, glass ceramic, and polymer.

5. The photovoltaic device of claim 1, further comprising:
a further thin-film semiconductor layer coupled to the second major surface of the substrate and including at least one photo-sensitive p-n junction therein,
wherein the light directing feature is operable to cause the incident light to propagate through the substrate and into the further semiconductor layer in a waveguide mode and to impinge upon the p-n junction thereof a plurality of times.

6. The photovoltaic device of claim 1, further comprising a light collecting device operable to direct solar light toward one of the plurality of side surfaces of the substrate such that the solar light is coupled into the substrate and into the semiconductor layer in the waveguide mode.

7. The photovoltaic device of claim 6, wherein the light collecting device is a solar concentrator having a focal axis directed toward the one of the plurality of side surfaces of the substrate.

8. The photovoltaic device of claim 6, wherein the light collecting device is a convex edge characteristic of the one of the plurality of side surfaces of the substrate.

9. The photovoltaic device of claim 1, further comprising at least one light redirective element disposed proximate to at least one of the plurality of side surfaces of the substrate, the at least one light redirective element being operable to cause the light that has reflected a plurality of times between the first and second major surfaces of the semiconductor layer in the waveguide mode to the at least one side surface to reverse and reflect a further plurality of times between the first and second major surfaces of the semiconductor layer in a waveguide mode and to impinge upon the p-n junction a further plurality of times.

10. The photovoltaic device of claim 9, wherein the light redirective element is at least one of a prismatic structure, lens structure, reflector structure, scattering surface structure, and diffractive surface structure formed on the at least one side surface.

11. A photovoltaic device, comprising:
a first substantially transparent substrate having first and second major surfaces and a plurality of side surfaces;
a first thin-film semiconductor layer coupled to the first major surface of the first substrate and including at least one photo-sensitive p-n junction therein;
a second substantially transparent substrate having first and second major surfaces and a plurality of side surfaces; and
a second thin-film semiconductor layer coupled to the first major surface of the second substrate and including at least one photo-sensitive p-n junction therein, wherein
the first and second thin-film semiconductor layers are disposed facing one another in a spaced apart configuration forming a gap therebetween, and
at least one light directing feature operable to cause incident light to propagate through the respective first and second substrates and into the respective first and second semiconductor layers in respective waveguide modes such that the light reflects a plurality of times between the first and second major surfaces thereof and impinges upon the respective p-n junctions a plurality of times.

12. The photovoltaic device of claim 11, wherein the light directing feature is operable to cause incident light to propagate through at least one composite structure of the device in a waveguide mode, wherein the at least one composite structure includes at least one of: (i) the first substrate and the first semiconductor layer; (ii) the second substrate and the second semiconductor layer; (iii) the gap and the first semiconductor layer; (iv) the gap and the second semiconductor layer; (v) the gap and the first and second semiconductor layers; and (vi) combinations of the above.

13. The photovoltaic device of claim 11, wherein the gap is between about 0.1-0.7 mm.

14. The photovoltaic device of claim 11, further comprising at least one rod disposed in the gap between the respective first and second semiconductor layers, wherein the at least one rod is operable to at least one of space the first and second semiconductor layers apart and focus at least some solar light into the gap such that the light propagates in the gap and into the respective semiconductor layers in waveguide modes impinging upon the respective p-n junctions a plurality of times.

15. A photovoltaic device, comprising:
a substantially transparent substrate having first and second major surfaces and a plurality of side surfaces; and
a thin-film semiconductor layer having first and second major surfaces, being coupled to the first major surface of the substrate, and including at least one photo-sensitive p-n junction therein; and
a light collecting device operable to direct solar light toward one of the plurality of side surfaces of the substrate such that the solar light is coupled into the substrate, through the substrate, and into the semiconductor layer in a waveguide mode such that the light reflects a plurality of times between the first and second major surfaces of the semiconductor layer and impinges upon the p-n junction a plurality of times.

16. The photovoltaic device of claim 15, wherein the light directing feature is operable to cause incident light to propagate through at least one composite structure of the device in a waveguide mode, wherein the composite structure includes the substrate and the semiconductor layer.

17. The photovoltaic device of claim 15, wherein:
the light collecting device includes a substantially cylindrical rod having a longitudinal slot extending along a wall thereof;
the substrate and thin-film semiconductor layer are located within the slot such that one of the plurality of side surfaces of the substrate abuts a bottom of the slot,
the rod includes optical properties that cause the solar light to couple into the substrate and into the semiconductor layer in the waveguide mode.

18. The photovoltaic device of claim 16, wherein the rod includes further optical properties that cause the solar light to couple into one of the major surfaces of the substrate.

19. The photovoltaic device of claim 16, wherein the rod is formed from glass, transparent polymer, and/or plexiglass.

20. The photovoltaic device of claim 16, wherein the light collecting device further includes at least one reflector located proximate to an outside surface of the rod and directing light exiting the wall of the rod back toward the substrate and thin-film semiconductor layer.

21. The photovoltaic device of claim 15, wherein:
the light collecting device includes a wedge-shaped rod having a longitudinal slot extending along a narrow edge thereof;
the substrate and thin-film semiconductor layer is located within the slot such that one of the plurality of side surfaces of the substrate abuts a bottom of the slot and
the wedge-shaped rod includes optical properties that cause the solar light to be directed toward the one of the plurality of side surfaces of the substrate and to direct light that would otherwise not couple into the substrate back toward the substrate and thin-film semiconductor layer.

22. The photovoltaic device of claim 21, wherein the wedge-shaped rod includes a convex domed surface opposite the slot defining a focal axis directed toward the one of the plurality of side surfaces of the substrate.

23. The photovoltaic device of claim 22, wherein:
the wedge-shaped rod includes at least one side surface extends from the narrow edge thereof outward and angles away from the substrate and thin-film semiconductor layer toward an edge of the convex domed surface; and
the at least one side surface is operable to direct light that would otherwise not couple into the substrate back toward the substrate and thin-film semiconductor layer.

24. The photovoltaic device of claim 23, wherein the at least one side surface is operable to cause the solar light to reflect back toward the substrate and thin-film semiconductor layer and to couple into one of the major surfaces of the substrate.

25. The photovoltaic device of claim 21, wherein the wedge-shaped rod is formed from glass, transparent polymer, and/or plexiglass.

26. The photovoltaic device of claim 15, wherein the light collecting device includes a solar concentrator having a focal axis directed toward the one of the plurality of side surfaces of the substrate.

27. The photovoltaic device of claim 26, wherein:
the light collecting device further includes at least one reflector having a first edge located proximate to the substrate and thin-film semiconductor layer and angling away therefrom toward an opposite edge of the at least one reflector and toward the solar concentrator, and
the at least one reflector being operable to direct light that would otherwise not couple into the substrate back toward the substrate and thin-film semiconductor layer.

28. The photovoltaic device of claim 27, wherein the at least one reflector is operable to cause the light to reflect back toward the substrate and thin-film semiconductor layer and to couple into one of the major surfaces of the substrate.

29. The photovoltaic device of claim 15, wherein the light collecting device includes an integrating-type hollow cylinder having a cylindrical wall defining an interior volume, the substrate and thin-film semiconductor layer being located at least partially within the interior volume, and the cylindrical wall including a longitudinal slot extending therealong defining an aperture for the solar light to enter the interior volume.

30. The photovoltaic device of claim 15, wherein the cylindrical wall includes a reflective interior surface operable to direct the light at least one of: (i) toward one of the plurality of side surfaces of the substrate such that the solar light is coupled into the substrate and into the semiconductor layer in the waveguide mode; and (ii) back toward the substrate and thin-film semiconductor layer and to couple into one of the major surfaces of the substrate.

31. The photovoltaic device of claim 15, wherein the light collecting device further includes a solar concentrator having a focal axis directed toward and through the longitudinal slot.

32. A photovoltaic device, comprising:
a substantially transparent substrate having first and second major surfaces and a plurality of side surfaces; and
a thin-film semiconductor layer coupled to the first major surface of the substrate and including at least one photo-sensitive p-n junction therein; and
a light collecting device including: (i) at least one solar concentrator having a focal axis operable to direct solar light toward one of the first and second major surfaces of the substrate, and (ii) at least one corresponding redirective element operable to direct the light entering the substrate through the one of the first and second major surfaces transversely with respect to the focal axis of the solar concentrator such that the solar light is coupled into the substrate and into the semiconductor layer in a waveguide mode,
wherein respective dielectric constant discontinuities proximate to the first and second major surfaces of the semiconductor layer are operable to cause incident light to reflect a plurality of times between first and second major surfaces of the semiconductor layer in the waveguide mode and to impinge upon the p-n junction a plurality of times.

33. The photovoltaic device of claim 32, wherein the light directing feature is operable to cause incident light to propagate through at least one composite structure of the device in a waveguide mode, wherein the composite structure includes the substrate and the semiconductor layer.

34. The photovoltaic device of claim 32, wherein:
the device includes a plurality of the thin-film semiconductor layers spaced apart from one another over at least one of the first and second major surfaces of the substrate; and
a plurality of the light collecting devices, each located to direct light into the substrate through the one of the first and second major surfaces thereof.

35. The photovoltaic device of claim 34, further comprising an AR coating on the first major surface of the substrate between at least some of the thin-film semiconductor layers.

36. The photovoltaic device of claim 32, wherein the redirective element is at least one of a reflective element and a prismatic element.

37. The photovoltaic device of claim 32, comprising a plurality of thin-film semiconductor layers, at least a first of the semiconductor layers coupled to the first major surface of the substrate and including first and second major surfaces, and each semiconductor layer including at least one photo-sensitive p-n junction therein.

38. The photovoltaic device of claim 37, wherein at least two of the thin-film semiconductor layers are stacked one atop the other.

39. A photovoltaic device, comprising:
a substantially transparent substrate having first and second major surfaces and a plurality of side surfaces;
a plurality of thin-film semiconductor layers, at least a first of the semiconductor layers coupled to the first major surface of the substrate and including first and second major surfaces, and each semiconductor layer including at least one photo-sensitive p-n junction therein; and
a light directing feature operable to cause incident light to propagate through the substrate and into the plurality of semiconductor layers in waveguide modes such that the light reflects a plurality of times between the first and second major surfaces of the plurality of semiconductor layers and impinges upon the p-n junctions a plurality of times.

40. The photovoltaic device of claim 39, wherein the light directing feature is operable to cause incident light to propagate through at least one composite structure of the device in a waveguide mode, wherein the composite structure includes the substrate and at least one of the semiconductor layers.

41. The photovoltaic device of claim 39, wherein at least two of the thin-film semiconductor layers are stacked one atop the other.
